(19) United States
(12) Patent Application Publication
(10) Pub. No.: US 2023/0360951 A1
(43) Pub. Date: Nov. 9, 2023

(54) APPARATUS FOR TRANSPORTING SUBSTRATE AND APPARATUS FOR TREATING SUBSTRATE

(71) Applicant: SEMES CO., LTD., Cheonan-si (KR)

(72) Inventors: Tae Kyung KONG, Cheonan-si (KR); Kiwon HAN, Anseong-si (KR); Jin Sung SUN, Cheonan-si (KR)

(73) Assignee: SEMES CO., LTD., Cheonan-si (KR)

(21) Appl. No.: 18/352,467

(22) Filed: Jul. 14, 2023

Related U.S. Application Data
(62) Division of application No. 17/065,641, filed on Oct. 8, 2020.

(30) Foreign Application Priority Data
Oct. 11, 2019 (KR) 10-2019-0126046

(51) Int. Cl. H01L 21/683; B25J 15/06; B25J 11/00; B25J 15/00; H01L 21/687

(52) U.S. Cl. CPC H01L 21/6838; B25J 15/0683; B25J 11/0095; B25J 15/0014; H01L 21/68707

(57) ABSTRACT

An apparatus for transporting a substrate includes an actuator, a robot arm, operation of which is controlled by the actuator, a robot hand including at least one intake vent having a predetermined separation distance from the supported substrate, a fixing unit that fixes the substrate supported on the robot hand, and an intake unit connected with the intake vent.

### CROSS-REFERENCE TO RELATED APPLICATIONS

This application is a divisional of U.S. application Ser. No. 17/065,641, filed on Oct. 8, 2020, which claims priority under 35 U.S.C. § 119 to Korean Patent Application No. 10-2019-0126046 filed on Oct. 11, 2019, in the Korean Intellectual Property Office, the entire contents of each of which are hereby incorporated by reference.

### BACKGROUND

Embodiments of the inventive concept described herein relate to an apparatus for transporting a substrate and an apparatus for treating a substrate.

In general, semiconductor devices are manufactured by depositing various materials on a substrate in thin film forms and subjecting the thin films to patterning. To this end, various processes such as a deposition process, an etching process, a cleaning process, a drying process, and the like are required. In each of the processes, the substrate is mounted and treated in a process chamber that provides an optimal condition for the corresponding process.

Among these semiconductor device manufacturing processes, a process such as etching, diffusion, chemical vapor deposition, or the like is performed by supplying a process gas under a predetermined atmosphere in a sealed process chamber and allowing the process gas to react with a wafer in the process chamber. In the semiconductor manufacturing process, to maintain a wafer chuck in the process chamber at a predetermined temperature, a chiller is used to cool the wafer chuck. A chiller for semiconductor manufacturing is mounted in an etching or deposition apparatus using plasma and precisely cools a chamber at high speed, thereby preventing damage to a wafer and maintaining the quality of the wafer constant. A chiller of a mechanical compression type is mainly used.

A wafer treating process other than a cleaning process is performed in a heating chamber that heats a wafer to a temperature of several hundreds of degrees as illustrated in FIG. 1. Accordingly, the wafer subjected to the wafer treating process has a large amount of heat inside and therefore has to be transported to a cooling chamber so as to be cooled.

### SUMMARY

Embodiments of the inventive concept provide a substrate transport apparatus and a substrate treating apparatus for efficiently treating a substrate.

Embodiments of the inventive concept provide a substrate transport apparatus and a substrate treating apparatus for removing heat from a substrate while removing particles.

The technical problems to be solved by the inventive concept are not limited to the aforementioned problems, and any other technical problems not mentioned herein will be clearly understood from the following description by those skilled in the art to which the inventive concept pertains.

According to an exemplary embodiment, an apparatus for transporting a substrate includes an actuator, a robot arm, operation of which is controlled by the actuator, a robot hand including at least one intake vent having a predetermined separation distance from the supported substrate, a fixing unit that fixes the substrate supported on the robot hand, and an intake unit connected with the intake vent.

In an embodiment, the intake vent may be formed in a position corresponding to a bottom surface of the supported substrate.

In an embodiment, the intake vent may be formed in a position corresponding to a side surface of the supported substrate.

In an embodiment, the intake vent may be formed in a higher position than an upper surface of the substrate.

In an embodiment, the apparatus may be provided on one side of a heating chamber.

According to an exemplary embodiment, an apparatus for treating a substrate includes a heating chamber that includes a heater and that heats the substrate and a transfer chamber including a transport robot that transports the heated substrate from the heating chamber. The transport robot includes an actuator, a robot arm, operation of which is controlled by the actuator, a robot hand including at least one intake vent having a predetermined separation distance from the supported substrate, a fixing unit that fixes the substrate supported on the robot hand, and an intake unit connected with the intake vent.

In an embodiment, the intake vent may be formed in a position corresponding to a bottom surface of the supported substrate.

In an embodiment, the intake vent may be formed in a position corresponding to a side surface of the supported substrate.

In an embodiment, the intake vent may be formed in a higher position than an upper surface of the substrate.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating substrate treating chambers in order according to the related art;

FIG. 2 is a view of substrate treating equipment as viewed from above;

FIG. 3 is a view illustrating the equipment of FIG. 2 when viewed in direction A-A;

FIG. 4 is a view illustrating the equipment of FIG. 2 when viewed in direction B-B;

FIG. 5 is a perspective view of a transport robot according to an embodiment of the inventive concept.

FIG. 6 is a sectional view taken along line I-I of FIG. 5;

FIG. 7 is a view illustrating a transport robot according to another embodiment;

FIG. 8 is a view illustrating a transport robot according to another embodiment; and

FIG. 9 is a sectional view taken along line II-II of FIG. 8.

### DETAILED DESCRIPTION

Hereinafter, embodiments of the inventive concept will be described in more detail with reference to the accompanying drawings. The inventive concept may, however, be embodied in different forms and should not be construed as limited to the embodiments set forth herein. Rather, these embodiments are provided so that the inventive concept will be thorough and complete, and will fully convey the scope of the inventive concept to those skilled in the art. In the drawings, the dimensions of components are exaggerated for clarity of illustration.

Equipment of this embodiment may be used to perform a photolithography process on a substrate such as a semiconductor wafer or a flat display panel. In particular, the equipment of this embodiment may be connected to an exposing apparatus and may be used to perform a coating process and a developing process on a substrate. In the following description, it will be exemplified that a wafer is used as a substrate.

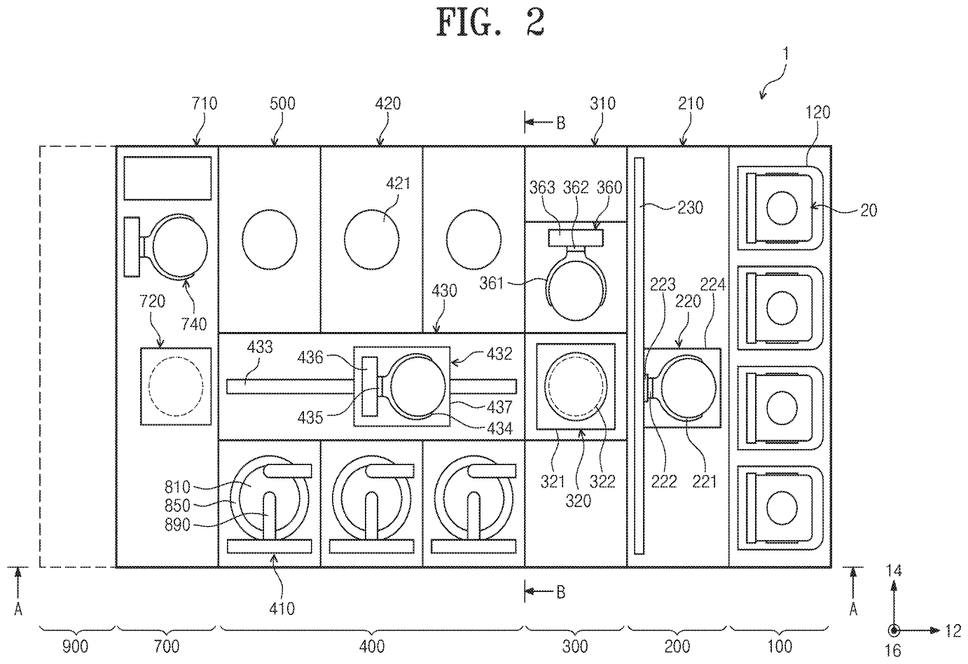

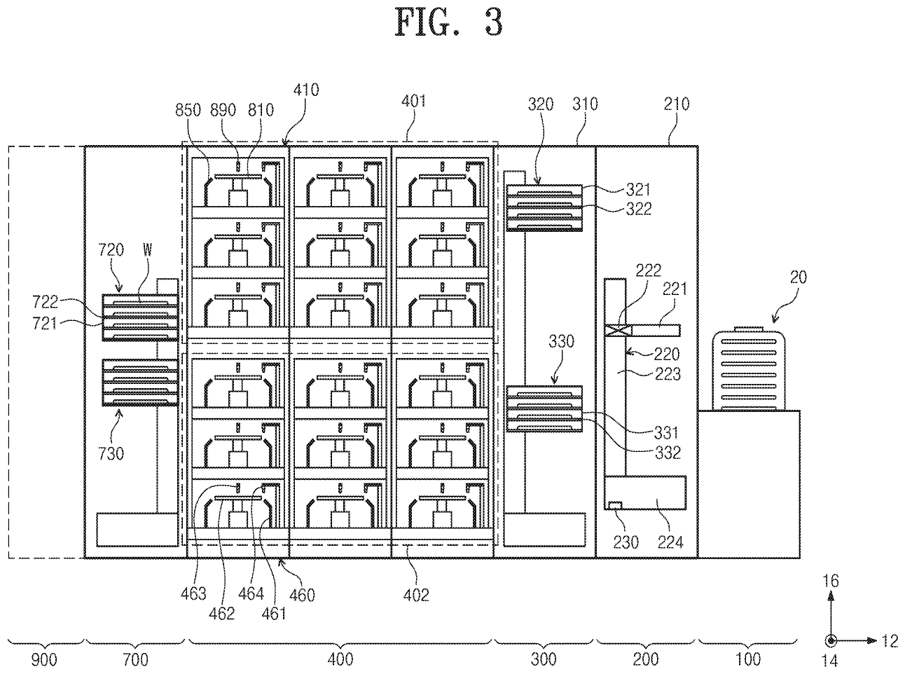

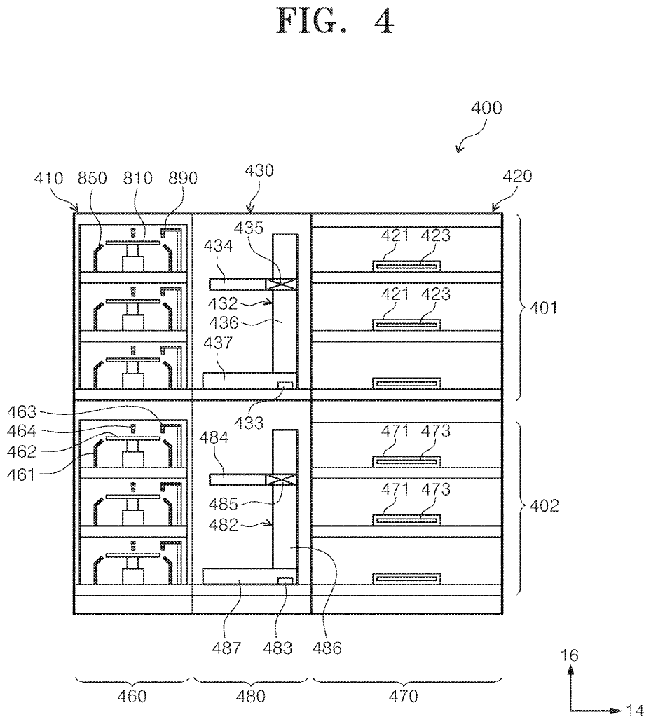

FIG. 2 is a view of substrate treating equipment as viewed from above. FIG. 3 is a view illustrating the equipment of FIG. 2 when viewed in direction A-A. FIG. 4 is a view illustrating the equipment of FIG. 2 when viewed in direction B-B.

Referring to FIGS. 2 to 4, the substrate treating equipment 1 includes a load port 100, an index module 200, a buffer module 300, a coating and developing module 400, and an interface module 700. The load port 100, the index module 200, the buffer module 300, the coating and developing module 400, and the interface module 700 are sequentially disposed in a row in one direction.

Hereinafter, a first direction 12 refers to a direction in which the load port 100, the index module 200, the buffer module 300, the coating and developing module 400, and the interface module 700 are disposed. A second direction 14 refers to a direction perpendicular to the first direction 12 when viewed from above, and a third direction 16 refers to a direction perpendicular to the first direction 12 and the second direction 14.

Substrates W are moved in a state of being received in a cassette 20. The cassette 20 has a structure that can be sealed from the outside. For example, a front open unified pod (FOUP) having a door at the front may be used as the cassette 20.

Hereinafter, the load port 100, the index module 200, the buffer module 300, the coating and developing module 400, and the interface module 700 will be described in detail.

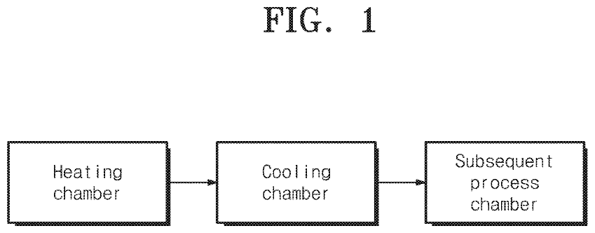

The load port 100 has a mounting table 120 on which the cassette 20 having the substrates W received therein is placed. A plurality of mounting tables 120 may be provided. The mounting tables 120 may be disposed in a row along the second direction 14. In FIG. 1, four mounting tables 120 are provided.

The index module 200 transports the substrates W between the cassette 20, which is placed on each of the mounting tables 120 of the load port 100, and the buffer module 300. The index module 200 has a frame 210, an index robot 220, and a guide rail 230. The frame 210 has a substantially rectangular parallelepiped shape with an empty space inside and is disposed between the load port 100 and the buffer module 300. The frame 210 of the index module 200 may be provided in a lower position than a frame 310 of the buffer module 300 that will be described below. The index robot 220 and the guide rail 230 are disposed in the frame 210. The index robot 220 has a structure capable of 4-axis driving such that a hand 221 for directly handling the substrates W is movable in the first direction 12, the second direction 14, and the third direction 16 and is rotatable about the central axis thereof. The index robot 220 has the hand 221, an arm 222, a support rod 223, and a base 224. The hand 221 is fixedly attached to the arm 222. The arm 222 has a retractable and rotatable structure. The support rod 223 is disposed such that the lengthwise direction thereof is parallel to the third direction 16. The arm 222 is coupled to the support rod 223 so as to be movable along the support rod 223. The support rod 223 is fixedly coupled to the base 224. The guide rail 230 is disposed such that the lengthwise direction thereof is parallel to the second direction 14. The base 224 is coupled to the guide rail 230 so as to be rectilinearly movable along the guide rail 230. Furthermore, although not illustrated, a door opener for opening and closing a door of the cassette 20 is additionally provided in the frame 210.

The buffer module 300 has a frame 310, a first buffer 320, a second buffer 330, and a buffer robot 360. The frame 310 has a rectangular parallelepiped shape with an empty space inside and is disposed between the index module 200 and the coating and developing module 400. The first buffer 320, the second buffer 330, and the buffer robot 360 are located in the frame 310. The second buffer 330 and the first buffer 320 are sequentially disposed along the third direction 16 from below. The first buffer 320 is located at the height corresponding to a coating module 401 of the coating and developing module 400 that will be described below, and the second buffer 330 is located at the height corresponding to a developing module 402 of the coating and developing module 400 that will be described below. The buffer robot 360 is located to be spaced apart from the second buffer 330 and the first buffer 320 by a predetermined distance in the second direction 14.

The first buffer 320 and the second buffer 330 each temporarily store a plurality of substrates W. The second buffer 330 has a housing 331 and a plurality of supports 332. The supports 332 are disposed in the housing 331 and are spaced apart from each other along the third direction 16. One substrate W is placed on each of the supports 332. The housing 331 has openings (not illustrated) that face the directions in which the index robot 220, the buffer robot 360, and a developer robot 482 are provided, respectively, such that the index robot 220, the buffer robot 360, and the developer robot 482 of the developing module 402, which will be described below, load the substrates W onto the supports 332 in the housing 331 or unload the substrates W from the supports 332. The first buffer 320 has a structure substantially similar to that of the second buffer 330. However, a housing 321 of the first buffer 320 has openings that face the directions in which the buffer robot 360 and a coater robot 432 located in the coating module 401 are provided. The number of supports 332 provided in the first buffer 320 may be the same as, or different from, the number of supports 332 provided in the second buffer 330. According to an embodiment, the number of supports 332 provided in the second buffer 330 may be larger than the number of supports 322 provided in the first buffer 320.

The buffer robot 360 transports the substrates W between the first buffer 320 and the second buffer 330. The buffer robot 360 has a hand 361, an arm 362, and a support rod 363. The hand 361 is fixedly attached to the arm 362. The arm 362 has a retractable structure and enables the hand 361 to move along the second direction 14. The arm 362 is coupled to the support rod 363 so as to be rectilinearly movable along the support rod 363 in the third direction 16. The support rod 363 has a length extending from the position corresponding to the second buffer 330 to the position corresponding to the first buffer 320. The support rod 363 may further extend upward or downward. The buffer robot 360 may be provided such that the hand 361 simply performs only 2-axis driving along the second direction 14 and the third direction 16.

The coating and developing module 400 performs a process of coating the substrates W with photoresist before an exposing process and performs a developing process on the substrates W after the exposing process. The coating and developing module 400 has a substantially rectangular parallelepiped shape. The coating and developing module 400 has the coating module 401 and the developing module 402. The coating module 401 and the developing module 402 are disposed on different floors so as to be divided from each other. According to an embodiment, the coating module 401 is located over the developing module 402.

The coating module 401 performs a process of coating the substrate W with a photosensitive liquid such as photoresist and performs a heat treatment process, such as heating, on the substrate W before and after the resist coating process. The coating module 401 has resist coating chambers 410, bake chambers 420, and a transfer chamber 430. The resist coating chambers 410, the transfer chamber 430, and the bake chambers 420 are sequentially disposed along the second direction 14. Accordingly, the resist coating chambers 410 and the bake chambers 420 are located to be spaced apart from each other in the second direction 14, with the transfer chamber 430 therebetween. The resist coating chambers 410 are arranged in the first direction 12 and the third direction 16. The bake chambers 420 are arranged in the first direction 12 and the third direction 16.

The transfer chamber 430 is located side by side with the first buffer 320 of the buffer module 300 in the first direction 12. The coater robot 432 and a guide rail 433 are located in the transfer chamber 430. The transfer chamber 430 has a substantially rectangular shape. The coater robot 432 transports the substrates W between the bake chambers 420, the resist coating chambers 400, and the first buffer 320 of the buffer module 300. The guide rail 433 is disposed such that the lengthwise direction thereof is parallel to the first direction 12. The guide rail 433 guides a rectilinear movement of the coater robot 432 in the first direction 12. The coater robot 432 has a hand 434, an arm 435, a support rod 436, and a base 437. The hand 434 is fixedly attached to the arm 435. The arm 435 has a retractable structure and enables the hand 434 to move in the horizontal direction. The support rod 436 is disposed such that the lengthwise direction thereof is parallel to the third direction 16. The arm 435 is coupled to the support rod 436 so as to be rectilinearly movable along the support rod 463 in the third direction 16. The support rod 436 is fixedly coupled to the base 437, and the base 437 is coupled to the guide rail 433 so as to be movable along the guide rail 433.

The resist coating chambers 410 all have the same structure. However, the types of photoresists used in the respective resist coating chambers 410 may differ from one another. For example, chemical amplification resist may be used as photoresist. The resist coating chambers 410 are provided as substrate treating apparatuses that coat the substrates W with photoresist.

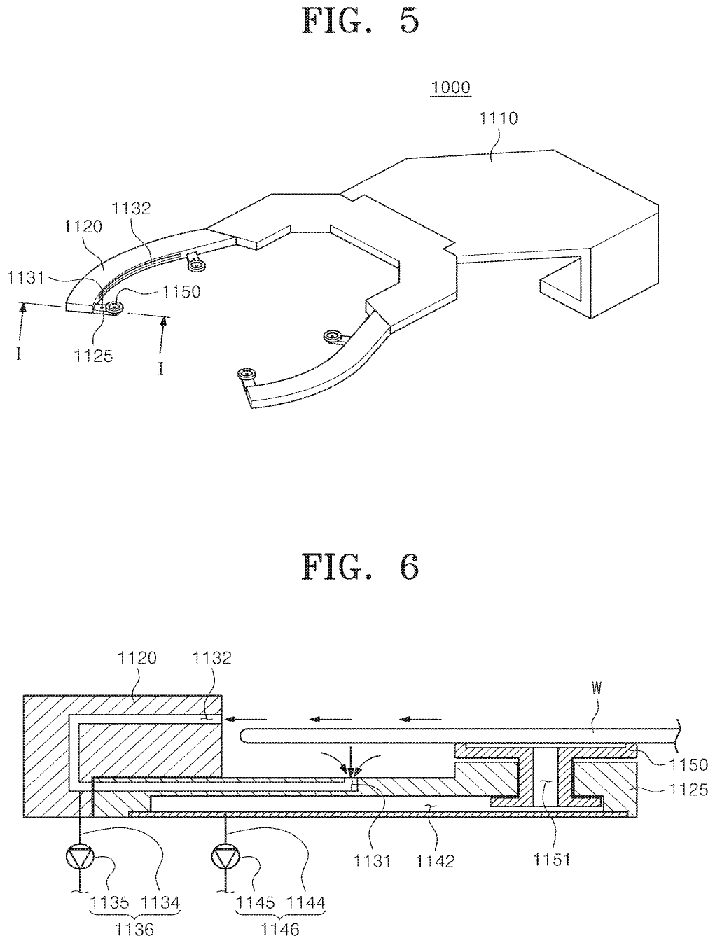

FIG. 5 is a perspective view of a transport robot 1000 according to an embodiment of the inventive concept. The transport robot 1000 may be the coater robot 432, the developer robot 482, the buffer robot 360, or the like. The transport robot 1000 may preferably transport a heated substrate and may be provided on one side of a heating chamber. For example, the heating chamber may be the bake chamber 420.

The transport robot 1000 includes a robot arm 1110 and a robot hand 1120. The robot hand 1120 includes support parts 1125. According to an embodiment, the robot hand 1120 includes four support parts 1125. Each of the support parts 1125 includes a suction pad 1150. The support part 1125 has a first intake vent 1131 formed therein. The robot hand 1120 has a second intake vent 1132 formed in a side surface thereof.

FIG. 6 is a sectional view taken along line I-I of FIG. 5.

Referring to FIG. 6, a suction hole 1151 is formed in the suction pad 1150. The suction hole 1151 is connected to a vacuum unit 1146 through a suction line 1142 formed in the support part 1125. The suction line 1142 is in fluid communication with the suction hole 1151. The vacuum unit 1146 includes a vacuum line 1144 and a vacuum pump 1145. When the vacuum pump 1145 operates, a substrate W placed on the suction pad 1150 is supported on the support part 1125 by vacuum pressure. The suction pad 1150, the suction line 1142, and the vacuum unit 1146 form a fixing unit that fixes the substrate W.

The first intake vent 1131 is formed in the support part 1125. The first intake vent 1131 is formed in an area corresponding to a bottom surface of the substrate W. The first intake vent 1131 has a predetermined separation distance from the supported substrate W. For example, an upper surface of the suction pad 1150 may be located in a higher position than an upper surface of a portion of the support part 1125 where the first intake vent 1131 is formed, and thus the substrate W supported on the suction pad 1150 may be spaced apart from the first intake vent 1131.

The second intake vent 1132 is formed in the side surface of the robot hand 1120. The second intake vent 1132 is formed in an area corresponding to a side surface of the substrate W. The second intake vent 1132 is preferably formed in a position higher than an upper surface of the substrate W. The second intake vent 1132 has a predetermined separation distance from the supported substrate W.

The first intake vent 1131 and the second intake vent 1132 are connected to an intake unit 1136. The intake unit 1136 includes an intake line 1134 and an intake pump 1135. The intake line 1134 is in fluid communication with the first intake vent 1131 and the second intake vent 1132. The intake pump 1135 is connected to the intake line 1134.

The first intake vent 1131 and the second intake vent 1132 remove heat from the substrate W. Furthermore, the first intake vent 1131 and the second intake vent 1132 suction and remove particles. The second intake vent 1132, which is formed in a position corresponding to the side surface of the substrate W, may have a higher particle removal efficiency than the first intake vent 1131. The second intake vent 1132 may have a slit shape. Although not illustrated, the second intake vent 1132 may be formed of a plurality of holes.

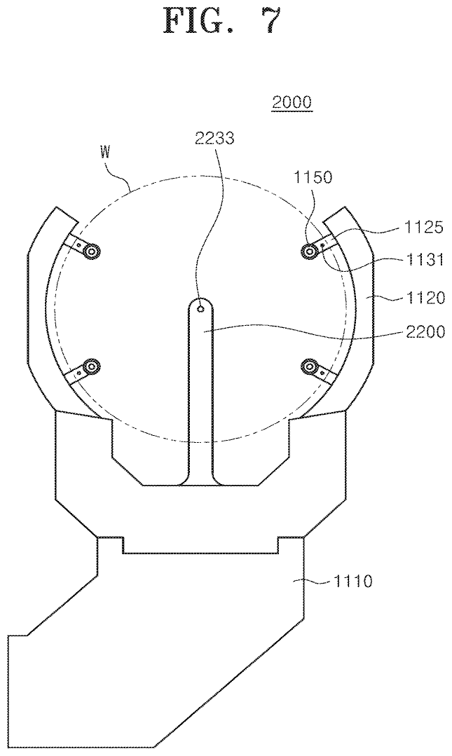

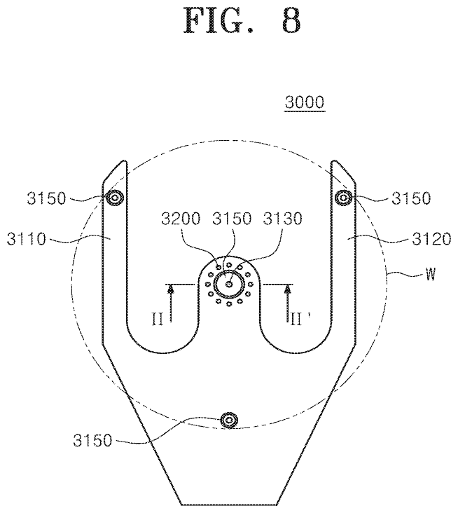

FIG. 7 is a view illustrating a transport robot 2000 according to another embodiment.

The transport robot 2000 further includes an intake plate 2200. The intake plate 2000 extends from the robot arm 1110 to a central area of a substrate W. The intake plate 2200 has a third intake vent 2233 formed therein. The third intake vent 2233 is located in the central area of the substrate W. The third intake vent 2233 has a predetermined separation distance from the supported substrate W. Descriptions of components having the same reference numerals as those described above with reference to FIGS. 5 and 6 will be omitted for the sake of brevity.

FIG. 8 is a view illustrating a transport robot 3000 according to another embodiment.

A hand of the transport robot 3000 includes a first blade 3110, a second blade 3120, and a third blade 3130. The first blade 3110 and the second blade 3120 support opposite end portions of a substrate W, and the third blade 3130 supports a central area of the substrate W. Each of the first blade 3110, the second blade 3120, and the third blade 3130 includes a suction pad 3150.

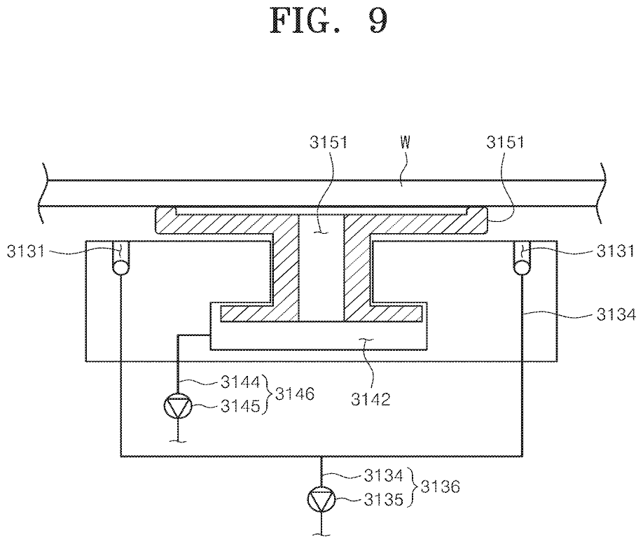

FIG. 9 is a sectional view taken along line II-II of FIG. 8. Referring to FIG. 9, a suction hole 3151 is formed in the suction pad 3150. The suction hole 3151 is connected to a vacuum unit 3146 through a suction line 3142. The vacuum unit 3146 includes a vacuum line 3144 and a vacuum pump 3145. When the vacuum pump 3145 operates, the substrate W placed on the suction pad 3150 is supported on the transport robot 3000 by vacuum pressure.

A plurality of third intake vents 3131 are formed in the third blade 3130. The third intake vents 3131 are formed in an area corresponding to a bottom surface of the substrate W. The third intake vents 3131 have a predetermined separation distance from the supported substrate W. The third intake vents 3131 are connected to an intake unit 3136. The intake unit 3136 includes intake lines 3134 and an intake pump 3135. The intake lines 3134 are in fluid communication with the third intake vents 3131. The intake pump 3135 is connected to the intake lines 3134. The third intake vents 3131 may remove heat from the substrate W by absorbing heat from the center of the bottom surface of the substrate W. Meanwhile, the intake pump 3135 and the intake lines 3134 may be connected to form one entity. However, the intake pump 3135 and the vacuum pump 3145 are separate from each other.

According to the embodiments of the inventive concept, the transport robots may remove heat from a substrate while removing particles. Furthermore, substrate treating speed may be increased because substrates can be cooled by the transport robots while being transported. In addition, equipment efficiency may be improved because a cooling chamber is omitted.

As described above, according to the embodiments of the inventive concept, the substrate transport apparatus and the substrate treating apparatus enable a substrate to be efficiently treated.

According to the embodiments of the inventive concept, the substrate transport apparatus and the substrate treating apparatus may remove heat from a substrate while removing particles.

Effects of the inventive concept are not limited to the above-described effects, and any other effects not mentioned herein may be clearly understood from this specification and the accompanying drawings by those skilled in the art to which the inventive concept pertains.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for transporting a substrate, the apparatus comprising:
an actuator;
a robot arm configured to be controlled by the actuator;
a robot hand provided at an end of the robot arm and configured to support the substrate, the robot hand including at least a first blade, a second blade, and a third blade, the first and second blades configured to support opposite ends of the substrate, the third blade configured to support a central area of the substrate, each of the first blade and the second blade including a first intake vent, one end of the first intake vent being at a side of the robot hand to face a side of the supported substrate, the one end of the first intake vent being apart from the side of the supported substrate by a first separation distance;
a fixing unit configured to fix the substrate supported on the robot hand; and
an intake unit connected with another end of the first intake vent,
wherein the first intake vent is at a higher position than an upper surface of the supported substrate,
the robot hand further includes a second intake vent connected to the intake unit, under a bottom surface of the supported substrate, and spaced apart from the bottom surface of the supported substrate by a second separation distance, and
the third blade includes a plurality of third intake vents configured to absorb heat from a bottom surface of the central area of the supported substrate.

2. The apparatus of claim 1, wherein the apparatus is provided on one side of a heating chamber.

3. The apparatus of claim 1, wherein the third blade includes a suction pad, which includes a suction hole and is configured to support the substrate thereon by vacuum pressure, and the plurality of third intake vents surrounding the suction pad.

4. The apparatus of claim 1, wherein the fixing unit includes:
a suction pad having at least one suction hole defined therein;
a suction line in fluid communication with the suction hole; and
a vacuum unit connected with the suction line.

5. The apparatus of claim 4, wherein
the robot hand includes a support part extending from the robot hand and configured to support the bottom surface of the supported substrate, and
the suction pad is provided on an end portion of the support part.

6. The apparatus of claim 5, wherein
the support part includes a second intake vent, one end of the second intake vent being at an upper surface of the support part, and
the suction pad further protrudes upward beyond an upper surface of a portion of the support part where the second intake vent is provided.

7. The apparatus of claim 6, wherein an intake line is in the support part.

8. The apparatus of claim 1, wherein the intake unit includes:
an intake line in fluid communication with the first intake vent; and
an intake pump connected to the intake line.

9. An apparatus for treating a substrate, the apparatus comprising:
a heating chamber including a heater, the heating chamber being configured to heat the substrate; and
a transfer chamber including a transport robot configured to transport the heated substrate from the heating chamber,
wherein the transport robot includes,
an actuator,
a robot arm configured to be controlled by the actuator,
a robot hand provided at an end of the robot arm and configured to support the substrate, the robot hand including at least a first blade, a second blade, and a third blade, the first and second blades configured to support opposite ends of a substrate, the third blade configured to support a central area of the substrate, each of the first blade and the second blade including a first intake vent, one end of the first intake vent being at a side of the robot hand to face a side of the supported substrate, the one end of the first intake vent being apart from the side of the supported substrate by a first separation distance,
a fixing unit configured to fix the substrate supported on the robot hand, and
an intake unit connected with another end of the first intake vent, and
wherein the first intake vent is at a higher position than an upper surface of the supported substrate,
the robot hand further includes a second intake vent connected to the intake unit, under a bottom surface of the supported substrate, and spaced apart from the bottom surface of the supported substrate by a second separation distance, and
the third blade includes a plurality of third intake vents configured to absorb heat from a bottom surface of the central area of the supported substrate.

10. The apparatus of claim 9, wherein the third blade includes a suction pad, which includes a suction hole and is configured to support the substrate thereon by vacuum pressure, and the plurality of third intake vents surrounding the suction pad.

11. The apparatus of claim 9, wherein the fixing unit includes:
a suction pad having at least one suction hole defined therein;
a suction line in fluid communication with the suction hole; and
a vacuum unit connected with the suction line.

12. The apparatus of claim 11, wherein
the robot hand includes a support part extending from the robot hand and configured to support the bottom surface of the supported substrate, and
the suction pad is provided on an end portion of the support part.

13. The apparatus of claim 12, wherein
the support part includes a second intake vent, one end of the second intake vent being at an upper surface of the support part, and
the suction pad further protrudes upward beyond an upper surface of a portion of the support part where the second intake vent is provided.

14. The apparatus of claim 13, wherein an intake line is in the support part.

15. The apparatus of claim 9, wherein the intake unit includes:
an intake line in fluid communication with the first intake vent; and
an intake pump connected to the intake line.

16. An apparatus for treating a substrate, the apparatus comprising:
a heating chamber including a heater, the heating chamber being configured to heat the substrate; and
a transfer chamber including a transport robot configured to transport the heated substrate from the heating chamber,
wherein the transport robot includes,
an actuator,
a robot arm configured to be controlled by the actuator,
a robot hand provided at an end of the robot arm, the robot hand including at least a first blade, a second blade, and a third blade, the first and second blades configured to support opposite ends of a substrate, the third blade configured to support a central area of the substrate, each of the first blade and the second blade including a support part extending from the robot hand and configured to support a bottom surface of the substrate and at least one first intake vent, one end of the first intake vent being at a side of the robot hand to face a side of the supported substrate, the one end of the first intake vent being apart from the side of the supported substrate by a first separation distance,
a fixing unit configured to fix the substrate supported on the robot hand, and
an intake unit connected with another end of the first intake vent,
wherein the fixing unit includes,
a suction pad having at least one suction hole defined therein, the suction pad further protruding upward beyond an upper surface of a portion of the support part,
a suction line in fluid communication with the suction hole, and
a vacuum unit connected with the suction line,
wherein the intake unit includes,
an intake line provided in the support part, the intake line being in fluid communication with the first intake vent, and
an intake pump connected to the intake line, and
wherein the first intake vent is at a higher position than an upper surface of the supported substrate,
the robot hand further includes at least one second intake vent connected to the intake unit, under a bottom surface of the supported substrate, and spaced apart from the bottom surface of the supported substrate by a second separation distance, and
the third blade includes a plurality of third intake vents configured to absorb heat from a bottom surface of the central area of the supported substrate.

17. The apparatus of claim 16, wherein the third blade includes a suction pad, which includes a suction hole and is configured to support the substrate thereon by vacuum pressure, and the plurality of third intake vents surrounding the suction pad.
